(19) United States
(12) Patent Application Publication
(10) Pub. No.: US 2026/0033390 A1
(43) Pub. Date: Jan. 29, 2026

(54) SEMICONDUCTOR PACKAGE AND METHOD OF FABRICATING THE SAME

(71) Applicant: Samsung Electronics Co., Ltd., Suwon-si (KR)

(72) Inventors: Taehyeong KIM, Suwon-si (KR); Jaeyong PARK, Suwon-si (KR)

(73) Assignee: Samsung Electronics Co., Ltd., Suwon-si (KR)

(21) Appl. No.: 19/055,917

(22) Filed: Feb. 18, 2025

(30) Foreign Application Priority Data
Jul. 26, 2024 (KR) 10-2024-0099728

(51) Int. Cl. H01L 25/16; H01L 23/00; H01L 23/31; H01L 23/48; H01L 23/498; H01L 23/538; H10B 80/00; H10D 80/30

(52) U.S. Cl. CPC H01L 25/16; H01L 23/3185; H01L 23/481; H01L 23/49811; H01L 24/16; H01L 24/29; H01L 24/32; H01L 24/73; H10B 80/00; H10D 80/30; H01L 23/5385; H01L 23/5386; H01L 24/05; H01L 24/96; H01L 24/97; H01L 2224/05624; H01L 2224/05644; H01L 2224/05647; H01L 2224/05655; H01L 2224/05669; H01L 2224/05684; H01L 2224/16148; H01L 2224/16227; H01L 2224/16238; H01L 2224/29017; H01L 2224/29018; H01L 2224/32145; H01L 2224/73204; H01L 2224/96; H01L 2224/97; H01L 2225/06513; H01L 2225/06544; H01L 2924/1431; H01L 2924/14361

(57) ABSTRACT

A semiconductor package may include a base chip, at least one chip stack module on the base chip, and a sealant on the base chip and sealing the at least one chip stack module. The at least one chip stack module may have an integral structure, in which a plurality of memory chips may be stacked and uniform. Each chip stack module of the at least one chip stack module may be on the base chip while having the integral structure.

### CROSS-REFERENCE TO RELATED APPLICATION

This application is based on and claims priority under 35 U.S.C. § 119 to Korean Patent Application No. 10-2024-0099728, filed on Jul. 26, 2024 in the Korean Intellectual Property Office, the disclosure of which is incorporated by reference herein in its entirety.

### BACKGROUND

Inventive concepts relate to a semiconductor package, and more particularly, to a semiconductor package including a chip stack structure in which semiconductor chips are stacked.

Electronic devices have increasingly been reduced in size and weight in accordance with the rapid development of the electronics industry and the demand of users. Along with the smaller sizes and lighter weights of electronic devices, semiconductor packages used for electronic devices also have been reduced in size and weight, and semiconductor packages may be required to have high reliability as well as high performance and/or high capacity. To implement semiconductor packages having smaller sizes, lighter weights, high performance, high capacity, and/or high reliability, research and development continues to be conducted on semiconductor chips including through-silicon via (TSV) structures and on semiconductor packages having chip stack structures in which such semiconductor chips are stacked.

### SUMMARY

Inventive concepts provide a semiconductor package including a chip stack structure that is capable of coping with base chips having various designs and functions and is uniformized.

Inventive concepts are not limited to the above aspects, and the above and other aspects of inventive concepts will be clearly understood by those of ordinary skill in the art from the following description.

According to an embodiment of inventive concepts, a semiconductor package may include a base chip; at least one chip stack module on the base chip; and a sealant on the base chip and sealing the at least one chip stack module. Each chip stack module of the at least one chip stack module may have an integral structure, in which a plurality of memory chips may be stacked and may be uniform, and each chip stack module of the at least one chip stack module may be on the base chip while having the integral structure.

According to an embodiment of inventive concepts, a semiconductor package may include a chip stack module having an integral structure, in which 4n memory chips may be stacked and may be uniform, the chip stack module including a bonding layer being between an adjacent two memory chips among the 4n memory chips, and n being a natural number. The 4n memory chips may include an uppermost memory chip on other memory chips. The other memory chips each may include a through-electrode. The uppermost memory chip may not include the through-electrode. A portion of the bonding layer may protrude from a side surface of each memory chip among the 4n memory chips, or a side surface of the bonding layer may be coplanar with a side surface of each of the 4n memory chips.

According to an embodiment of inventive concepts, a semiconductor package may include a package substrate; at least one upper package on the package substrate; and a logic device on the package substrate and adjacent to the at least one upper package. The at least one upper package may include a chip stack module having an integral structure in which a plurality of memory chips are stacked and uniform.

According to an embodiment of inventive concepts, a method of fabricating a semiconductor package may include fabricating a plurality of chip stack modules, each of the plurality of chip stack modules having an integral structure in which a plurality of memory chips may be stacked and may be uniform; stacking the plurality of chip stack modules on a base chip substrate, the base chip substrate including a plurality of base chips; scaling the plurality of chip stack modules on the base chip substrate with a sealant to provide a structure on the base chip substrate, the structure on the base chip substrate including the sealant and the plurality of chip stack modules; and individualizing, through a first sawing process, the base chip substrate and the structure on the base chip substrate into a plurality of semiconductor packages that each may include a base chip and one or more of the plurality of chip stack modules on the base chip, the base chip being among the plurality of base chips.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to an embodiment;

FIGS. 2A and 2B are cross-sectional views of semiconductor packages according to some embodiments;

FIGS. 3A to 4B are cross-sectional views of semiconductor packages according to some embodiments;

FIGS. 5A and 5B are respectively a perspective view and a cross-sectional view of a system package according to an embodiment;

FIGS. 6A to 6C are cross-sectional views of system packages according to some embodiments;

FIGS. 7A to 7G are cross-sectional views schematically illustrating processes of a method of fabricating a semiconductor package, according to an embodiment;

FIGS. 8A and 8B are cross-sectional views schematically illustrating a process of fabricating an initial chip stack module of FIG. 7A; and

FIG. 9 is a cross-sectional view schematically illustrating a process of fabricating the initial chip stack module of FIG. 7A.

### DETAILED DESCRIPTION OF THE EMBODIMENTS

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise.

Hereinafter, embodiments of inventive concepts will be described in detail with reference to the accompanying drawings. Like components are denoted by like reference numerals throughout the specification, and repeated descriptions thereof are omitted.

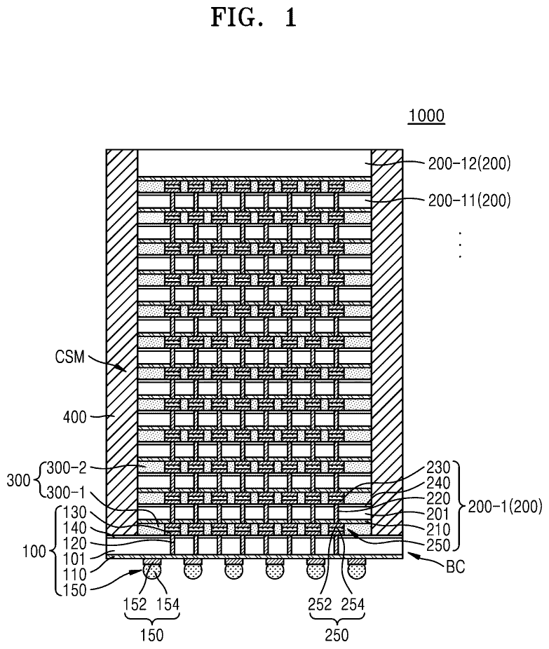

FIG. 1 is a cross-sectional view of a semiconductor package according to an embodiment.

Referring to FIG. 1, a semiconductor package 1000 of the present embodiment may include a base chip 100, a chip stack module CSM, a bonding layer 300, and a sealant 400.

The base chip 100 may include a substrate body 101, a device layer 110, a through-electrode 120, an upper pad 130, a protection layer 140, and an external connection terminal 150. The base chip 100 may be greater in size than memory chips 200 of the chip stack module CSM arranged on the base chip 100, as shown in FIG. 1. However, the size of the base chip 100 is not limited thereto. For example, in some embodiments, the base chip 100 may have a substantially equal size to the memory chips 200 of the chip stack module CSM.

The substrate body 101 may include, for example, a semiconductor element, such as silicon (Si) or germanium (Ge). In addition, the substrate body 101 may include a compound semiconductor, such as silicon carbide (SiC), gallium arsenide (GaAs), indium arsenide (InAs), or indium phosphide (InP). The substrate body 101 may have a silicon-on-insulator (SOI) structure. For example, the substrate body 101 may include a buried oxide (BOX) layer. The substrate body 101 may include a conductive region, for example, a structure, such as an impurity-doped well or an impurity-doped source/drain region. The substrate body 101 may include various device isolation structures, such as a shallow trench isolation (STI) structure.

The device layer 110 may include various types of devices. For example, the device layer 110 may include various active devices and/or passive devices, for example, a field effect transistor (FET) such as a planar FET or a FinFET, memory such as flash memory, dynamic random access memory (DRAM), static random access memory (SRAM), electrically erasable programmable read-only memory (EEPROM), phase-change random access memory (PRAM), magnetoresistive random access memory (MRAM), ferroelectric random access memory (FeRAM), or resistive random access memory (RRAM), a logic device such as an AND, an OR, or a NOT, a system large-scale integration (LSI), a CMOS imaging sensor (CIS), and a micro-electro-mechanical system (MEMS).

The device layer 110 may include an integrated circuit layer in which the devices described above are arranged, and a multi-wiring layer arranged on the integrated circuit layer. The multi-wiring layer may connect at least two devices to each other, may connect devices to a conductive region of the substrate body 101, or may electrically connect devices to the external connection terminal 150. In addition, the multi-wiring layer may connect the through-electrode 120 and the external connection terminal 150 to each other. The multi-wiring layer may include, for example, wiring lines and contacts or vias. In the semiconductor package 1000 of the present embodiment, although the device layer 110 is arranged under the through-electrode 120, the device layer 110 may be arranged on the through-electrode 120 in some embodiments. For example, a positional relation between the device layer 110 and the through-electrode 120 may be relative.

In the semiconductor package 1000 of the present embodiment, the base chip 100 may include a plurality of logic devices in the device layer 110. The base chip 100 may be arranged under the chip stack module CSP to integrate signals from the memory chips 200 and to transfer the signals to the outside of the semiconductor package 1000 and may transfer signals and power from outside the semiconductor package 1000 to the memory chips 200. Therefore, the base chip 100 may be referred to as a buffer chip or an interface chip.

In some embodiments, the base chip 100 may include a controller configured to control signal transfer between the memory chips 200 and an external device. When the base chip 100 includes a controller, the base chip 100 may be referred to as a logic chip, a control chip, or the like. In addition, in some embodiments, the base chip 100, as a logic chip or a control chip, may include a power management integrated circuit (PMIC) configured to manage power or clocks. For reference, when the base chip 100 is referred to as a buffer chip or the like, the memory chips 200 of the chip stack module CSM may be referred to as core chips.

In the semiconductor package 1000 of the present embodiment, the base chip 100 is not limited to a buffer chip or a logic chip. For example, the base chip 100 may include a plurality of memory devices in the device layer 110. Therefore, the base chip 100 may be a memory chip.

The through-electrode 120 may extend from the upper surface of the substrate body 101 to the lower surface of the substrate body 101, and thus, may pass through the substrate body 101. In some embodiments, the through-electrode 120 may extend to the inside of the device layer 110. In the semiconductor package 1000 of the present embodiment, the substrate body 101 may include Si, and thus, the through-electrode 120 may be referred to as a through-silicon via (TSV).

The through-electrode 120 may have a column shape and may include a barrier film corresponding to an outer surface and a buried conductive layer inside the barrier film. The barrier film may include at least one material selected from Ti, TiN, Ta, TaN, Ru, Co, Mn, WN, Ni, and NiB. The buried conductive layer may include at least one material selected from Cu, a Cu alloy such as CuSn, CuMg, CuNi, CuZn, CuPd, CuAu, CuRe, or CuW, W, a W alloy, Ni, Ru, and Co. An insulating layer may be arranged between the through-electrode 120 and the substrate body 101 or between the through-electrode 120 and the device layer 110. The insulating layer may include, for example, an oxide film, a nitride film, a carbide film, a polymer, or a combination thereof.

The upper pad 130 may be arranged on the upper surface of the substrate body 101 and may be connected to the through-electrode 120. The upper pad 130 may include, for example, at least one of aluminum (Al), copper (Cu), nickel (Ni), tungsten (W), platinum (Pt), and gold (Au). In the semiconductor package 1000 of the present embodiment, the upper pad 130 may include Cu. However, the material of the upper pad 130 is not limited to Cu.

The protection layer 140 may be formed on the substrate body 101. The protection layer 140 may include an insulating layer, for example, an oxide film, a nitride film, a carbide film, a polymer, or a combination thereof. In the semiconductor package 1000 of the present embodiment, the protection layer 140 may include, for example, a silicon oxide film, a silicon nitride film, or a silicon oxynitride film. However, the material of the protection layer 140 is not limited to the materials set forth above. The through-electrode 120 may extend through the protection layer 140, and the upper pad 130 may be arranged on the upper surface of the through-electrode 120. In some embodiments, the upper pad 130 may be arranged on the upper surface of the through-electrode 120 such that the upper pad 130 passes through the protection layer 140.

The external connection terminal 150 may be arranged on the lower surface of the base chip 100 and may be electrically connected to the through-electrode 120 via the multi-wiring layer of the device layer 110. Although not shown, a chip pad may be arranged on the lower surface of the base chip 100, and the external connection terminal 150 may be arranged on the chip pad. In some embodiments, a pillar 152 of the external connection terminal 150 may function as a chip pad, and in this case, a separate chip pad may not be formed.

The external connection terminal 150 may include a pillar 152 and a solder 154. The pillar 152 may have a circular column shape and may include, for example, nickel (Ni), copper (Cu), palladium (Pd), platinum (Pt), gold (Au), or a combination thereof. The solder 154 may be arranged on the pillar 152 and may have a spherical shape or a ball shape. The solder 154 may include, for example, tin (Sn), indium (In), bismuth (Bi), antimony (Sb), copper (Cu), silver (Ag), zinc (Zn), lead (Pb), and/or an alloy thereof. For example, the solder 154 may include Sn, Pb, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, or the like. An intermediate layer may be formed in a contact interface region between the pillar 152 and the solder 154. The intermediate layer may include an intermetallic compound (IMC) that is formed by a reaction between metal materials in the solder 154 and the pillar 152 at a relatively high temperature.

The chip stack module CSM may be stacked on the base chip 100. The chip stack module CSM may include a plurality of memory chips 200 and the bonding layer 300. In the semiconductor package 1000 of the present embodiment, the chip stack module CSM may include twelve memory chips 200, for example, first to twelfth memory chips 200-1 to 200-12. However, the number of memory chips 200 of the chip stack module CSM is not limited to twelve. For example, the chip stack module CSM may include at least two and less than twelve memory chips or may include more than twelve memory chips.

For reference, in the semiconductor package 1000 of the present embodiment, the chip stack module CSM may include 4n memory chips (where n is a natural number). Accordingly, the chip stack module CSM may include memory chips by as many as a multiple of 4, such as 4, 8, or 12. In addition, every 4 memory chips 200 of the chip stack module CSM may have the same stack-ID and may be tested and operated together. For example, when the chip stack module CSM includes twelve memory chips, the first to fourth memory chips 200-1 to 200-4 may have a first stack-ID, the fifth to eighth memory chips 200-5 to 200-8 may have a second stack-ID, and the ninth to twelfth memory chips 200-9 to 200-12 may have a third stack-ID. However, in the semiconductor package 1000 of the present embodiment, the chip stack module CSM is not limited to the memory chips 200 as many as multiples of 4 and stack-IDs corresponding thereto. For example, the chip stack module CSM may include the memory chips 200 as many as multiples of 2 and stack-IDs corresponding thereto or may include the memory chips 200 as many as multiples of 8 and stack-IDs corresponding thereto.

All the memory chips 200 of the chip stack module CSM may have the same size and structure. However, as shown in FIG. 1, a top memory chip, for example, the twelfth memory chip 200-12, arranged at the uppermost position among the memory chips 200 of the chip stack module CSM may not include a through-electrode. Hereinafter, descriptions are made with reference to the first semiconductor chip 200-1 for convenience.

The first semiconductor chip 200-1 may include a substrate body 201, a device layer 210, a through-electrode 220, an upper pad 230, a protection layer 240, and a bump 250. Descriptions of the substrate body 201, the upper pad 230, and the protection layer 240 are the same as the descriptions of the substrate body 101, the upper pad 130, and the protection layer 140 of the base chip 100.

The device layer 210 of the first semiconductor chip 200-1 may include a plurality of memory devices. For example, the device layer 210 may include volatile memory devices, such as DRAM or SRAM, or non-volatile memory devices, such as PRAM, MRAM, FeRAM, or RRAM. For example, in the semiconductor package 1000 of the present embodiment, the first semiconductor chip 200-1 may include DRAM devices in the device layer 210. Therefore, the first semiconductor chip 200-1 may be a DRAM chip. In addition, the first semiconductor chip 200-1 may be a DRAM chip for high-bandwidth memory (HBM), and thus, the semiconductor package 1000 of the present embodiment may be an HBM package. However, the semiconductor package 1000 of the present embodiment is not limited to an HBM package.

The through-electrode 220 may pass through the substrate body 201 or may extend to the inside of the device layer 210 through the substrate body 201. For example, the first semiconductor chip 200-1 may be divided into a cell area and a pad area, and when the through-electrode 220 is formed only in the pad area, the through-electrode 220 may pass through the substrate body 201 to extend to the inside of the device layer 210. Other descriptions of the through-electrode 220 except the above description are the same as the descriptions of the through-electrode 120 of the base chip 100.

The bump 250 may be similar to the external connection terminal 150 of the base chip 100. Therefore, the bump 250 may include a pillar 252 and a solder 254. In some embodiments, the pillar 252 may function as a chip pad of the first semiconductor chip 200-1. The external connection terminal 150 is arranged on the lower surface of the base chip 100, whereas the bump 250 may be arranged between the first semiconductor chip 200-1 and the base chip 100. Specifically, the bump 250 may be arranged between a chip pad on the lower surface of the device layer 210 of the first semiconductor chip 200-1 and the upper pad 130 of the base chip 100. In addition, other memory chips 200 arranged on or over the first semiconductor chip 200-1 may each be connected to a memory chip 200 directly thereunder via the bump 250. As shown in FIG. 1, the size and pitch of the bump 250 may be less than those of the external connection terminal 150. In addition, the thickness of the bump 250 may be less than that of the external connection terminal 150.

In the semiconductor package 1000 of the present embodiment, the chip stack module CSM may have an integral structure in which a plurality of memory chips 200 that are substantially identical are stacked and uniformized. In addition, the chip stack module CSM having a uniformized integral structure may be directly stacked on the base chip 100 through one stacking process. Therefore, only the chip stack module CSM having passed a test may be stacked on the base chip 100, thereby significantly improving semiconductor package yield. In addition, the chip stack module CSM and the base chip 100 may be fabricated independently of each other, thereby increasing the degree of freedom in terms of the space and time of a fabrication process. Furthermore, the chip stack module CSM and the base chip 100 may be fabricated and tested independently of each other, thereby clarifying the guarantee area of process quality between the chip stack module CSM and the base chip 100. The chip stack module CSM is independently fabricated, and thus, restrictions on the size and height of a protrusion of the bonding layer 300 may be removed.

For reference, when a semiconductor package is fabricated by stacking memory chips one-by-one on a base chip, whether there are defects or not is determined by performing a test on a final structure of the semiconductor package. In the case of such fabrication and test methods, a defect may occur in the base chip or at least one of the memory chips in a stacking process. Therefore, the semiconductor package is determined to be defective and discarded, and thus, the yield thereof may be reduced. In particular, because bonding is performed by a method of thermal compression bonding (TCB) when a memory chip is stacked, whenever the memory chip is stacked, repetitive pressure may be applied to the base chip, and thus, defects of the base chip may increase. In addition, in the case of such fabrication and test methods, it may be ambiguous whether there is an issue in the base chip, the memory chip, or the stacking process. When memory chips are stacked one-by-one, the size and height of a protrusion of a bonding layer may be limited. In other words, because a sealant needs to cover even the protrusion of the bonding layer, the size of the protrusion of the bonding layer, which protrudes from a side surface of a memory chip, may be limited, and the height by which the protrusion of the bonding layer permeates the upper surface of the memory chip, in particular, the upper surface of the top memory, may be limited.

On the other hand, in the case of the semiconductor package 1000 of the present embodiment, because the chip stack module CSM having a uniformized integral structure is stacked on the base chip 100 by one stacking process, defects of the base chip 100 in the stacking process may be minimized. Therefore, the yield of the semiconductor package 1000 may improve. In addition, the chip stack module CSM and the base chip 100, which each have passed a test, are coupled to each other, and thus, the guarantee area of process quality may be clarified. Furthermore, because the chip stack module CSM is independently fabricated, the size and height of the protrusion of the bonding layer 300 may be adjusted, and thus, restrictions on the size and height of the protrusion of the bonding layer 300 may be removed. The chip stack module CSM, which has a uniformized integral structure, of the semiconductor package 1000 of the present embodiment may be flexibly applied to the base chip 100 having diverse designs and functions. Therefore, the chip stack module CSM of the semiconductor package 1000 of the present embodiment may early respond to custom base chips, custom semiconductor packages, or the like in the future.

The bonding layer 300 may be arranged between the base chip 100 and the first memory chip 200-1 and between two adjacent memory chips to surround the side surface of the bump 250. The bonding layer 300 may include, for example, a non-conductive film (NCF). For example, the NCF may be used as a bonding layer when a semiconductor chip is bonded by a TCB method in a semiconductor chip stacking process. However, the material of the bonding layer 300 is not limited to the NCF.

Bonding layers 300 may be classified into a module-chip bonding layer 300-1 and an inter-chip bonding layer 300-2. The module-chip bonding layer 300-1 may be arranged between the chip stack module CSM and the base chip 100 and may not be included in the chip stack module CSM. The inter-chip bonding layer 300-2 may be arranged between adjacent memory chips 200 of the chip stack module CSM and may be included in the chip stack module CSM. Because the module-chip bonding layer 300-1 and the inter-chip bonding layer 300-2 respectively have similar functions and structures, the module-chip bonding layer 300-1 and the inter-chip bonding layer 300-2 are collectively referred to as the bonding layer 300 hereinafter without distinction except for the case particularly requiring descriptions.

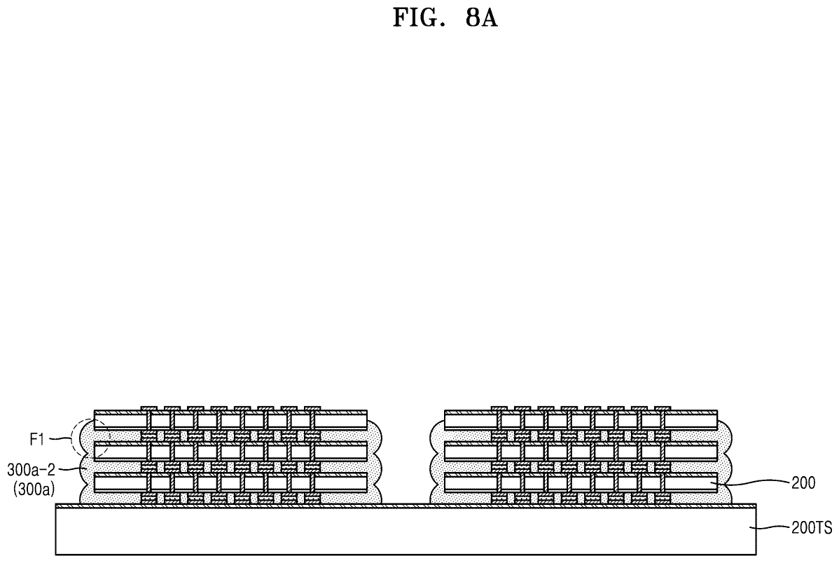

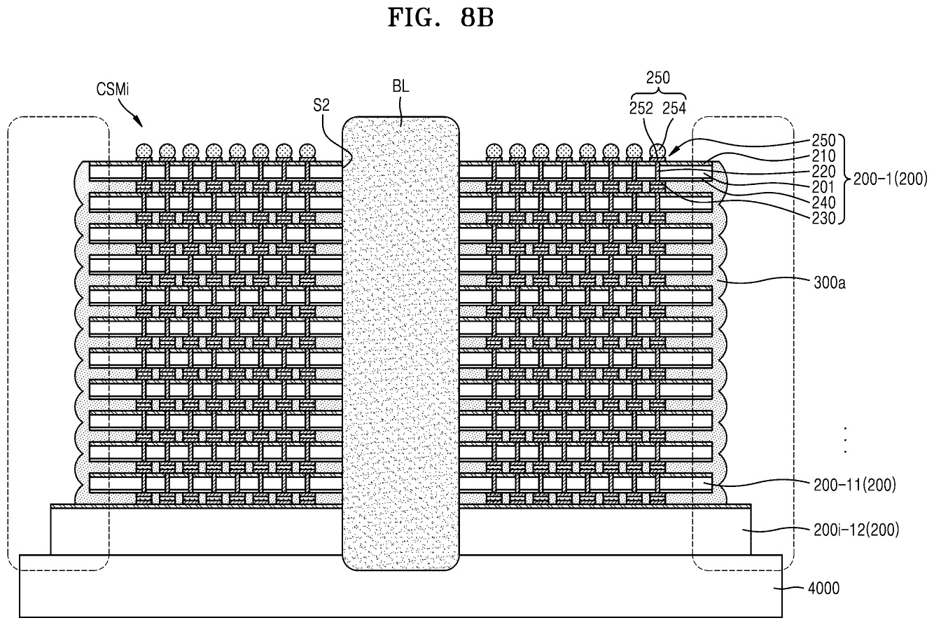

As shown in FIG. 1, the side surface of the bonding layer 300 may be substantially coplanar with the respective side surfaces of the memory chips 200. The shape of the side surface of the bonding layer 300 may be adjusted in a sawing process for individualizing the chip stack module CSM, when the chip stack module CSM is fabricated. The shape of the side surface of the bonding layer 300 is described below in more detail with reference to FIGS. 8A and 8B. In addition, the module-chip bonding layer 300-1 of the bonding layer 300 may have a protrusion. However, the chip stack module CSM is stacked on the base chip 100 by one stacking process, and thus, the protrusion of the module-chip bonding layer 300-1 may be minimized.

The sealant 400 may surround a side surface of the chip stack module CSM on the base chip 100. Specifically, the sealant 400 may surround the side surface of the bonding layer 300 between the base chip 100 and the chip stack module CSM, the side surface of each of the memory chips 200 of the chip stack module CSM, and the side surface of the bonding layer 300 between the memory chips 200. As shown in FIG. 1, the sealant 400 may not cover the upper surface of the top memory chip, for example, the twelfth memory chip 200-12, of the chip stack module CSM. Therefore, the upper surface of the twelfth memory chip 200-12 may be exposed from the sealant 400. However, in some embodiments, the sealant 400 may cover the upper surface of the top memory chip of the chip stack module CSM. The sealant 400 may include, for example, an epoxy mold compound (EMC). However, the material of the sealant 400 is not limited to the EMC.

In the semiconductor package 1000 of the present embodiment, the chip stack module CSM may have an integral structure in which the plurality of memory chips 200 are stacked and uniformized. In addition, the chip stack module CSM having a uniformized integral structure may be stacked on the base chip 100 by one stacking process. Therefore, only the chip stack module CSM having passed a test may be stacked on the base chip 100, thereby significantly improving the yield of the semiconductor package 1000. In addition, in the semiconductor package 1000 of the present embodiment, the chip stack module CSM and the base chip 100 may be fabricated independently of each other, thereby increasing the degree of freedom in terms of the space and time of a fabrication process. Furthermore, in the semiconductor package 1000 of the present embodiment, the chip stack module CSM and the base chip 100 may be fabricated and tested independently of each other, thereby clarifying the guarantee area of process quality between the chip stack module CSM and the base chip 100. The chip stack module CSM is independently fabricated, and thus, restrictions on the size and height of the protrusion of the bonding layer 300 may be removed.

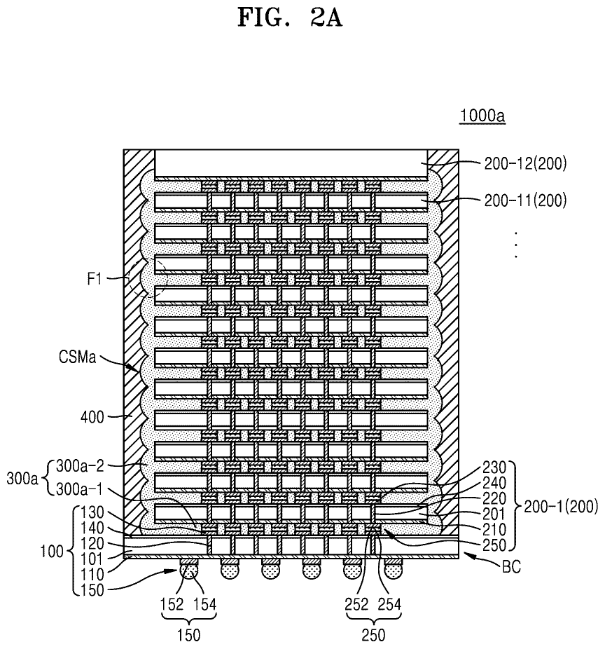

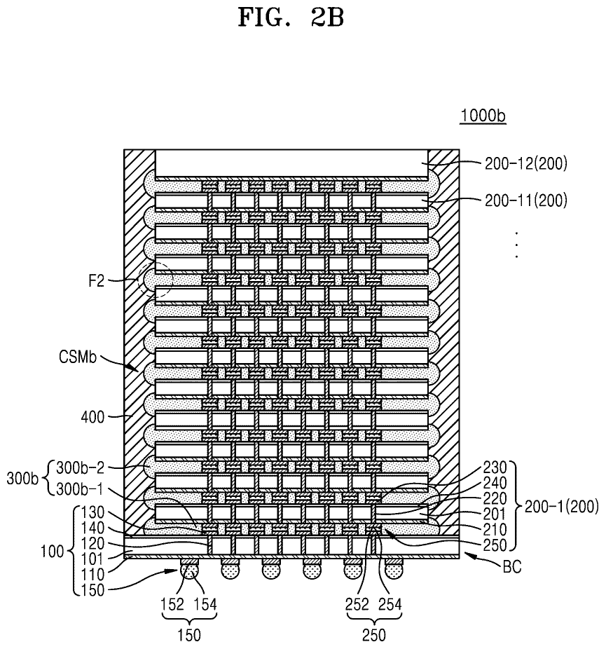

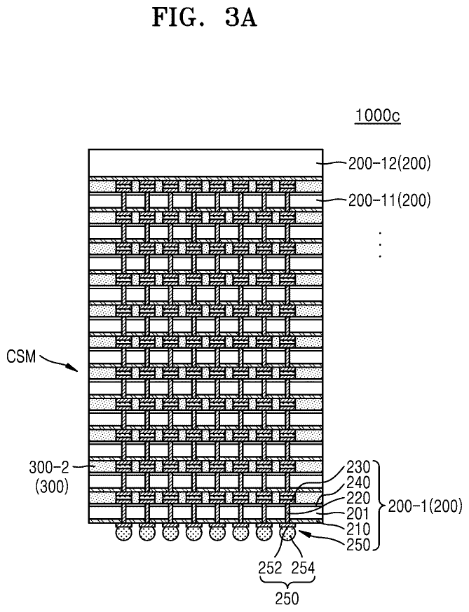

FIGS. 2A and 2B are cross-sectional views of semiconductor packages according to some embodiments. Repeated descriptions given with reference to FIG. 1 are briefly made or omitted.

Referring to FIG. 2A, a semiconductor package 1000a of the present embodiment may be different in a structure of a bonding layer 300a from the semiconductor package 1000 of FIG. 1. Specifically, the semiconductor package 1000a of the present embodiment may include a base chip 100, a chip stack module CSMa, a bonding layer 300a, and a sealant 400. Descriptions of the base chip 100 and the sealant 400 are the same as given in the descriptions of the semiconductor package 1000 of FIG. 1. In addition, descriptions of the chip stack module CSMa except for the bonding layer 300a are the same as given in the descriptions of the semiconductor package 1000 of FIG. 1.

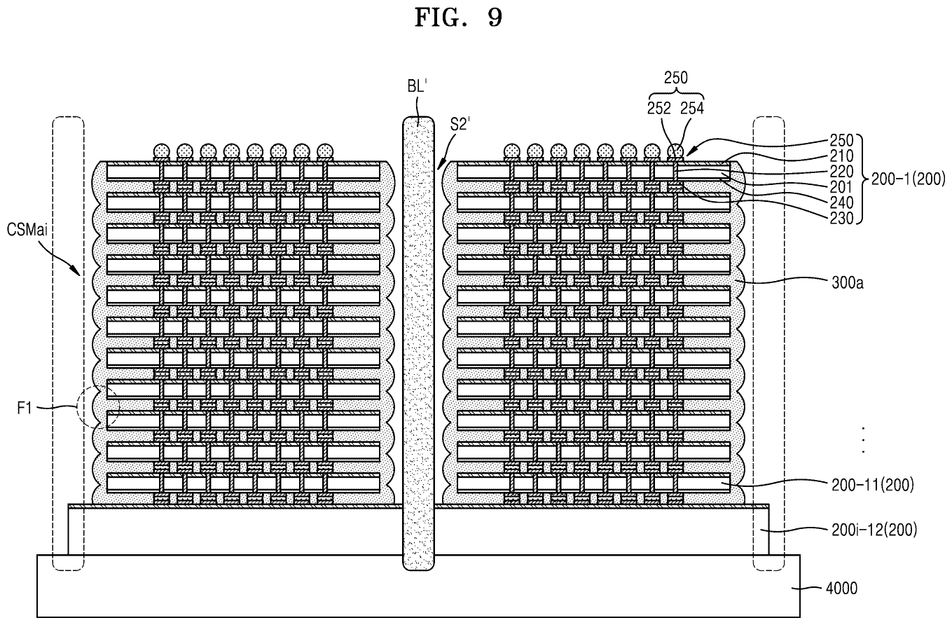

In the semiconductor package 1000a of the present embodiment, the bonding layer 300a may include a protrusion F1. The protrusion F1 of the bonding layer 300a may have a structure protruding from the side surface of each of the memory chips 200. The protrusion F1 of the bonding layer 300a may be naturally generated due to the flowability of the bonding layer 300a, when the memory chip 200 is stacked by a TCB method. However, in the case of the semiconductor package 1000 of FIG. 1, because respective outer portions of the bonding layer 300a and the memory chips 200 are removed together in a sawing process when manufacturing the chip stack module CSM, the bonding layer 300 may not include a protrusion. On the other hand, in the semiconductor package 1000a of the present embodiment, an outer portion of the bonding layer 300a may be maintained in a sawing process, and thus, the bonding layer 300a may include a protrusion F1. The shape of the protrusion F1 of the bonding layer 300a is described below in more detail with reference to FIG. 9.

In the semiconductor package 1000a of the present embodiment, bonding layers 300a may be classified into a module-chip bonding layer 300a-1 and an inter-chip bonding layer 300a-2. In addition, the module-chip bonding layer 300a-1 may not be included in the chip stack module CSMa, and the inter-chip bonding layer 300a-2 may be included in the chip stack module CSMa. Respective protrusions F1 of the module-chip bonding layer 300a-1 and the inter-chip bonding layer 300a-2 may be connected to each other on the side surface of the first memory chip 200-1. In addition, respective protrusions F1 of adjacent inter-chip bonding layers 300a-2 may be connected to each other on the side surface of the memory chip 200 corresponding thereto.

Referring to FIG. 2B, a semiconductor package 1000b of the present embodiment may be different in a structure of a bonding layer 300b from the semiconductor package 1000a of FIG. 2A. Specifically, the semiconductor package 1000b of the present embodiment may include a base chip 100, a chip stack module CSMb, a bonding layer 300b, and a sealant 400. Descriptions of the base chip 100 and the sealant 400 are the same as given in the descriptions of the semiconductor package 1000 of FIG. 1. In addition, descriptions of the chip stack module CSMb except for the bonding layer 300b are the same as given in the descriptions of the semiconductor package 1000 of FIG. 1.

In the semiconductor package 1000b of the present embodiment, the bonding layer 300b may include a protrusion F2. The protrusion F2 may have a structure protruding from the side surface of each of the memory chips 200. In the semiconductor package 1000b of the present embodiment, protrusions F2 of adjacent bonding layers 300b may be apart from each other not to be connected to each other on the side surface of the memory chip 200 corresponding thereto. Specifically, respective protrusions F2 of a module-chip bonding layer 300b-1 and an inter-chip bonding layer 300b-2 may be apart from each other on the side surface of the first memory chip 200-1. In addition, respective protrusions F2 of adjacent inter-chip bonding layers 300b-2 may be apart from each other on the side surface of the memory chip 200 corresponding thereto. The shape of the protrusion F2 of the bonding layer 300b may be adjusted by adjusting the viscosity of the bonding layer 300b, the temperature, pressure, and time in a TCB method, and the like, when the memory chip 200 is stacked by the TCB method.

In some embodiments, a semiconductor package may include a chip stack module from which a bonding layer is omitted. For example, by stacking memory chips of the chip stack module through hybrid copper bonding (HCB), the bonding layer may be omitted from the chip stack module. For reference, HCB may refer to a combination of pad-to-pad bonding and insulator-to-insulator bonding. More specifically, in general, pads may be respectively arranged on a lower surface and an upper surface of a memory chip and may have a structure passing through a protection layer arranged on each of the lower surface and the upper surface of the memory chip. The protection layer may include, for example, an insulator, such as a silicon oxide film or a silicon nitride film. Accordingly, pads and a protection layer on an upper surface of a lower memory chip may be respectively coupled to pads and a protection layer on a lower surface of an upper memory chip, thereby performing HCB. Because a pad is generally formed of Cu, pad-to-pad bonding is also referred to as Cu-to-Cu bonding.

In addition, in a semiconductor package of some embodiments, a chip stack module may include memory chips from which through-electrodes are omitted. Therefore, the chip stack module may have an integral structure in which the memory chips having no through-electrode are stacked and uniformized. Because the memory chips of the chip stack module include no through-electrode, signal transfer between the memory chips and a base chip may be performed by, for example, wireless communication.

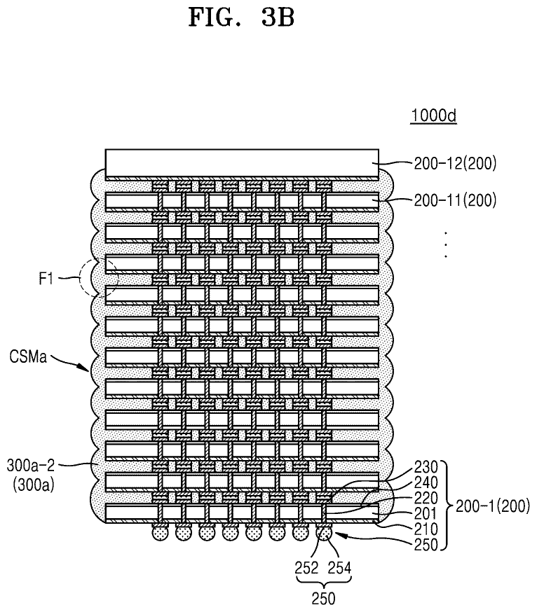

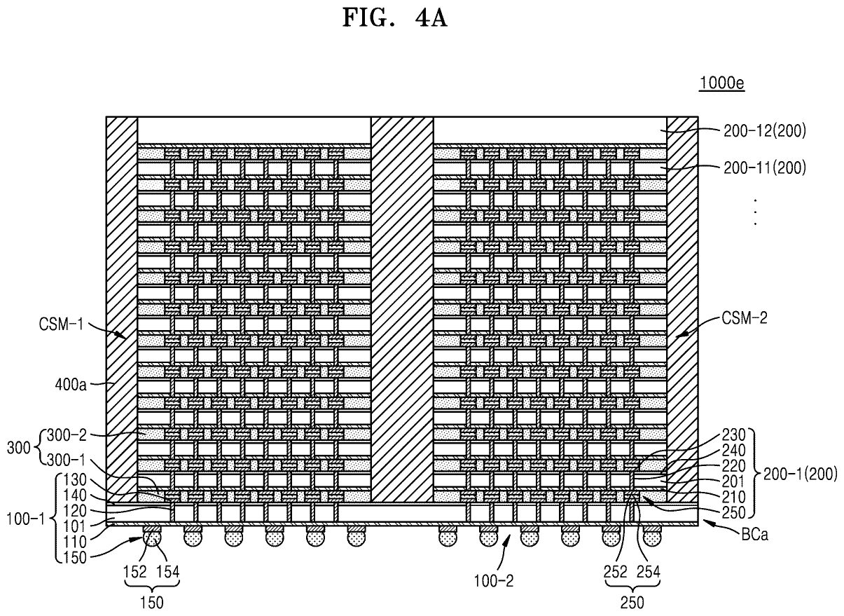

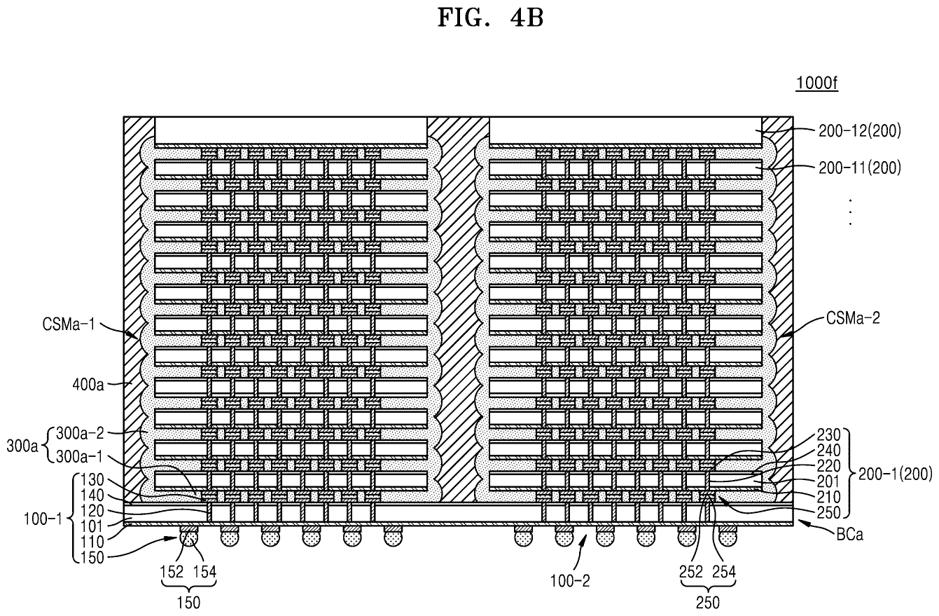

FIGS. 3A to 4B are cross-sectional views of semiconductor packages according to some embodiments. Repeated descriptions given with reference to FIGS. 1 to 2B are briefly made or omitted.

Referring to FIG. 3A, a semiconductor package 1000c of the present embodiment may be different from the semiconductor package 1000 of FIG. 1 in that the semiconductor package 1000c does not include a base chip and a sealant. Specifically, the semiconductor package 1000c of the present embodiment may include only a chip stack module CSM and may omit the base chip and the sealant. Because the semiconductor package 1000c of the present embodiment includes only the chip stack module CSM, the bonding layer 300 may include the inter-chip bonding layer 300-2 in the chip stack module CSM and may omit the module-chip bonding layer 300-1. As shown in FIG. 3A, the side surface of the bonding layer 300 may be substantially coplanar with the side surface of the memory chip 200.

The semiconductor package 1000c of the present embodiment may be stacked directly on an interposer, a Si-bridge, or the like without a base chip and be used. For example, the interposer, the Si-bridge, or the like may include devices performing functions of a base chip. In such a case, no base chip is required, and the chip stack module CSM from which a base chip is omitted, such as the semiconductor package 1000c of the present embodiment, may be stacked directly on an interposer, a Si-bridge, or the like.

Referring to FIG. 3B, a semiconductor package 1000d of the present embodiment may be different in the structure of the bonding layer 300a from the semiconductor package 1000c of FIG. 3A. Specifically, the semiconductor package 1000d of the present embodiment may include only the chip stack module CSMa and may omit a base chip and a sealant. Because the semiconductor package 1000d of the present embodiment includes only the chip stack module CSMa, the bonding layer 300a may include the inter-chip bonding layer 300a-2 in the chip stack module CSMa and may omit the module-chip bonding layer 300a-1.

In the semiconductor package 1000d of the present embodiment, the bonding layer 300a may include a protrusion F1. The protrusion F1 may have a structure protruding from the side surface of each of the memory chips 200. The protrusion F1 of the bonding layer 300a may be formed by maintaining an outer portion of the bonding layer 300a when individualization into chip stack modules CSMa is performed through a sawing process, as described regarding the semiconductor package 1000a of FIG. 2A. Although not shown, the bonding layer 300a may include protrusions F2 that are apart from each other, like the bonding layer 300b of the chip stack module CSMb of the semiconductor package 1000b of FIG. 2B. The semiconductor package 1000d of the present embodiment may also be stacked directly on an interposer, a Si-bridge, or the like without a base chip and be used.

Referring to FIG. 4A, a semiconductor package 1000e of the present embodiment may be different from the semiconductor package 1000 of FIG. 1 in that the semiconductor package 1000e includes two chip stack modules (that is, CSM-1 and CSM-2) on a base chip BCa. Specifically, the semiconductor package 1000e of the present embodiment may include a base chip BCa, two chip stack modules (that is, CSM-1 and CSM-2), a bonding layer 300, and a sealant 400a.

The base chip BCa may be divided into two portions to correspond to the two chip stack modules (that is, CSM-1 and CSM-2) that are stacked on the base chip BCa. For example, the base chip BCa may include a first base chip portion 100-1 corresponding to a first chip stack module CSM-1 and a second base chip portion 100-2 corresponding to a second chip stack module CSM-2. Descriptions of each of the first base chip portion 100-1 and the second base chip portion 100-2 are the same as the descriptions of the base chip 100 of the semiconductor package 1000 of FIG. 1.

As shown in FIG. 4A, the first chip stack module CSM-1 may be stacked on the first base chip portion 100-1, and the second chip stack module CSM-2 may be stacked on the second base chip portion 100-2. Descriptions of each of the first chip stack module CSM-1 and the second chip stack module CSM-2 are the same as the descriptions of the chip stack module CSM of the semiconductor package 1000 of FIG. 1.

The sealant 400a may surround side surfaces of the two chip stack modules (that is, CSM-1 and CSM-2) on the base chip BCa. In addition, as shown in FIG. 4A, the sealant 400a may fill a space between the first chip stack module CSM-1 and the second chip stack module CSM-2. The sealant 400a may not cover the upper surface of the top memory chip, for example, the twelfth memory chip 200-12, of each of the first chip stack module CSM-1 and the second chip stack module CSM-2. However, in some embodiments, the sealant 400a may cover the upper surface of the top memory chip of each of the first chip stack module CSM-1 and the second chip stack module CSM-2.

In the semiconductor package 1000e of the present embodiment, although two chip stack modules (that is, CSM-1 and CSM-2) are stacked on the base chip BCa, the number of chip stack modules stacked on the base chip BCa is not limited to two. For example, three or more chip stack modules may be stacked on the base chip BCa. When an even number of chip stack modules are stacked, to optimize the planar size of the base chip BCa, the chip stack modules may be arranged in a 2-dimensional array structure on the base chip BCa.

Referring to FIG. 4B, a semiconductor package 1000f of the present embodiment may be different in the structure of the bonding layer 300a from the semiconductor package 1000e of FIG. 4A. Specifically, the semiconductor package 1000f of the present embodiment may include a base chip BCa, two chip stack modules (that is, CSMa-1 and CSMa-2), a bonding layer 300a, and a sealant 400a. Descriptions of the base chip BCa and the sealant 400a are the same as given in the descriptions of the semiconductor package 1000c of FIG. 4A. In addition, descriptions of the two chip stack modules (that is, CSMa-1 and CSMa-2) except for the bonding layer 300a are the same as given in the descriptions of the semiconductor package 1000e of FIG. 4A.

In the semiconductor package 1000f of the present embodiment, the bonding layer 300a may include a protrusion F1. The protrusion F1 may have a shape protruding from the side surface of each of the memory chips 200. The protrusion F1 of the bonding layer 300a may be formed by maintaining an outer portion of the bonding layer 300a when individualization into chip stack modules (that is, CSMa-1 and CSMa-2) is performed through a sawing process, as described regarding the semiconductor package 1000a of FIG. 2A. Although not shown, the bonding layer 300a may include protrusions F2 that are apart from each other, like the bonding layer 300b of the chip stack module CSMb of the semiconductor package 1000b of FIG. 2B.

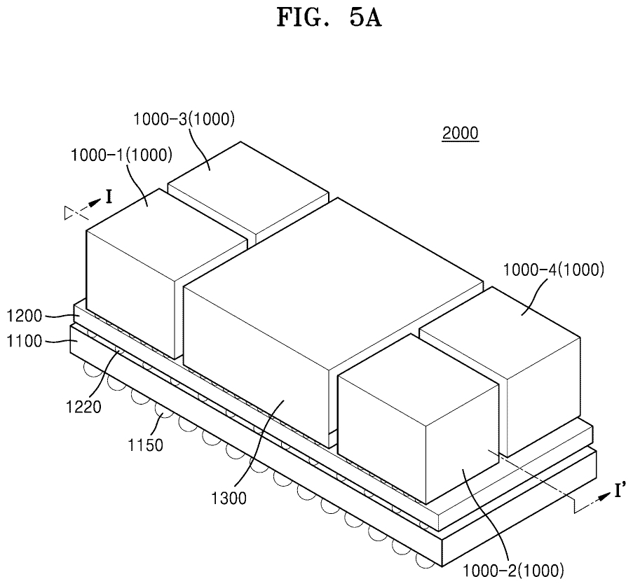

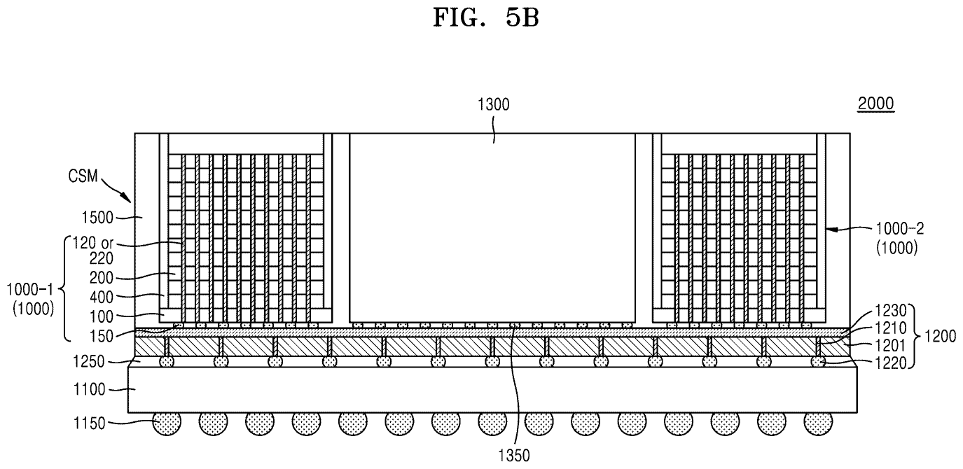

FIGS. 5A and 5B are respectively a perspective view and a cross-sectional view of a system package according to an embodiment, and in particular, FIG. 5B is a cross-sectional view of the system package, taken along a line I-I′ of FIG. 5A. FIG. 1 is also referred to for descriptions, and repeated descriptions given with reference to FIGS. 1 to 4B are briefly made or omitted.

Referring to FIGS. 5A and 5B, a system package 2000 of the present embodiment may include a semiconductor package 1000, a package substrate 1100, an interposer 1200, a logic device 1300, and an external sealant 1500.

As shown in FIG. 5A, the semiconductor package 1000 may include first to fourth semiconductor packages 1000-1 to 1000-4. For example, two semiconductor packages 1000 may be arranged on the interposer 1200 on each of two sides of the logic device 1300. However, in the system package 2000 of the present embodiment, the number of semiconductor packages 1000 is not limited to four. For example, one to three semiconductor packages 1000 or five or more semiconductor packages 1000 may be arranged on the interposer 1200.

The semiconductor package 1000 may include, for example, the semiconductor package 1000 of FIG. 1. Therefore, the semiconductor package 1000 may include the chip stack module CSM. More specifically, the semiconductor package 1000 may include the base chip 100, the chip stack module CSM, and the sealant 400. In addition, the chip stack module CSM may be arranged on the base chip 100 and may have an integral structure in which a plurality of memory chips 200 are stacked and uniformized. The base chip 100 and the memory chips 200 may respectively include through-electrodes 120 and 220 therein. Other descriptions of the semiconductor package 1000 except for the above description are the same as given in the descriptions of the semiconductor package 1000 of FIG. 1. However, in FIG. 5B, because the semiconductor package 1000 is illustrated while reduced in size, a bonding layer and a bump are not shown.

In the system package 2000 of the present embodiment, the semiconductor package 1000 may be, for example, an HBM package. Therefore, each of the memory chips 200 of the chip stack module CSM may be a DRAM chip. In the system package 2000 of the present embodiment, the semiconductor package 1000 is not limited to the semiconductor package 1000 of FIG. 1. For example, instead of the semiconductor package 1000 of FIG. 1, one of the semiconductor packages 1000a to 1000f of FIGS. 2A to 4B may be applied as the semiconductor package 1000 to the system package 2000 of the present embodiment.

The package substrate 1100 is a support substrate, and the interposer 1200, the semiconductor package 1000, the logic device 1300, and the like may be stacked on the package substrate 1100. The package substrate 1100 may include at least one layer of wiring lines therein. When wiring lines are formed in multiple layers, wiring lines in different layers may be connected to each other by vertical vias. The package substrate 1100 may include, for example, a ceramic substrate, a printed circuit board (PCB), a glass substrate, an interposer substrate, or the like. A first connection terminal 1150, such as a bump or a solder ball, may be arranged on the lower surface of the package substrate 1100. The first connection terminal 1150 may cause the system package 2000 to be stacked on a system substrate, a main board, or the like that is external to the system package 2000.

The interposer 1200 may include an interposer substrate 1201, a through-electrode 1210, a second connection terminal 1220, and a wiring layer 1230. The semiconductor package 1000 and the logic device 1300 may be mounted on the package substrate 1100 by the medium of the interposer 1200. The interposer 1200 may connect the semiconductor package 1000 and the logic device 1300 to each other. In addition, the interposer 1200 may connect each of the semiconductor package 1000 and the logic device 1300 to the package substrate 1100.

The interposer substrate 1201 may include, for example, Si. Therefore, the interposer 1200 may be a Si-interposer. The through-electrode 1210 may extend through the interposer substrate 1201. Because the interposer substrate 1201 includes silicon, the through-electrode 1210 may correspond to a TSV. The through-electrode 1210 may extend to the wiring layer 1230 and be connected to wiring lines of the wiring layer 1230. Depending on embodiments, the interposer 1200 may include only a wiring layer therein and may not include a through-electrode. The wiring layer 1230 may be arranged on the upper surface or the lower surface of the interposer substrate 1201. For example, a positional relation between the wiring layer 1230 and the through-electrode 1210 may be relative. A pad on the upper surface of the interposer 1200 may be connected to the through-electrode 1210 via the wiring layer 1230.

The second connection terminal 1220 may be arranged on the lower surface of the interposer 1200 and may be connected to the through-electrode 1210. The interposer 1200 may be stacked on the package substrate 1100 via the second connection terminal 1220. The second connection terminal 1220 may be connected to the pad on the upper surface of the interposer 1200 via the through-electrode 1210 and the wiring lines of the wiring layer 1230.

In the system package 2000 of the present embodiment, the interposer 1200 may be used to convert or transfer electrical signals between the semiconductor package 1000 and the logic device 1300. Therefore, the interposer 1200 may not include devices, such as active devices or passive devices. However, in some embodiments, the interposer 1200 may include devices for controlling signal transfer. An underfill 1250 may be filled between the interposer 1200 and the package substrate 1100 and between second connection terminals 1220. In some embodiment, the underfill 1250 may be replaced by a bonding layer or a bonding film.

The logic device 1300 may be stacked on a central portion of the interposer 1200 via an external connection terminal 1350. The logic device 1300 may have a chip structure or a package structure. In the system package 2000 of the present embodiment, the logic device 1300 may have a chip structure. For example, the logic device 1300 may be a logic chip. The logic device 1300 may include a plurality of logic devices therein. The logic devices may include, for example, devices, such as an AND, a NAND, an OR, a NOR, an exclusive OR (XOR), an exclusive NOR (XNOR), an inverter (INV), an adder (ADD), a delay (DLY), a filter (FIL), a multiplexer (MXT/MXIT), an OR/AND/INVERTER (OAI), an AND/OR (AO), an AND/OR/INVERTER (AOI), a D flip-flop, a reset flip-flop, a master-slave flip-flop, a latch, a counter, or a buffer. The logic devices may perform various signal processing, such as analog signal processing, analog-to-digital (A/D) conversion, and control. The logic device 1300 may be referred to as, according to the function thereof, a central processing unit (CPU) chip, a system-on-glass (SOG) chip, a micro-processor unit (MPU) chip, a graphic processing unit (GPU) chip, a neural processing unit (NPU) chip, an application processor (AP) chip, a control chip, or the like.

The external sealant 1500 may cover and seal the logic device 1300 and the semiconductor package 1000 on the interposer 1200. As shown in FIG. 5B, the external sealant 1500 may not cover the upper surface of each of the logic device 1300 and the semiconductor package 1000. However, in some embodiments, the external sealant 1500 may cover the upper surface of at least one of the logic device 1300 and the semiconductor package 1000. Although not shown, the system package 2000 of the present embodiment may further include a second external sealant for covering and sealing the interposer 1200 and the external sealant 1500 on the package substrate 1100.

For reference, the structure of the system package 2000 as in the present embodiment is referred to as a 2.5-dimensional (2.5D) package structure, and the 2.5D package structure may be a relative concept with respect to a 3-dimensional (3D) package structure in which all semiconductor chips are stacked together and there is no interposer. Both the 2.5D package structure and the 3D package structure may be included in a system-in-package (SIP) structure. In addition, although the system package 2000 of the present embodiment is also a semiconductor package, the term “system package” is used to terminologically distinguish the system package 2000 from the semiconductor package 1000 that is a component of the system package 2000.

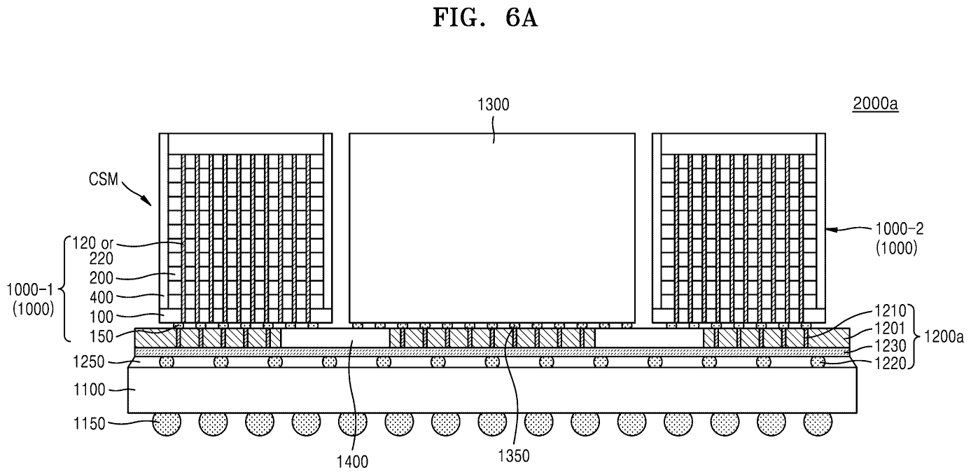

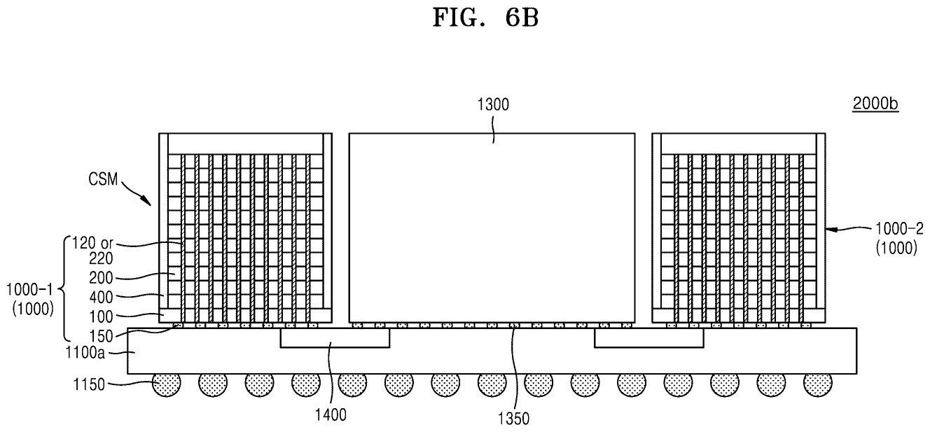

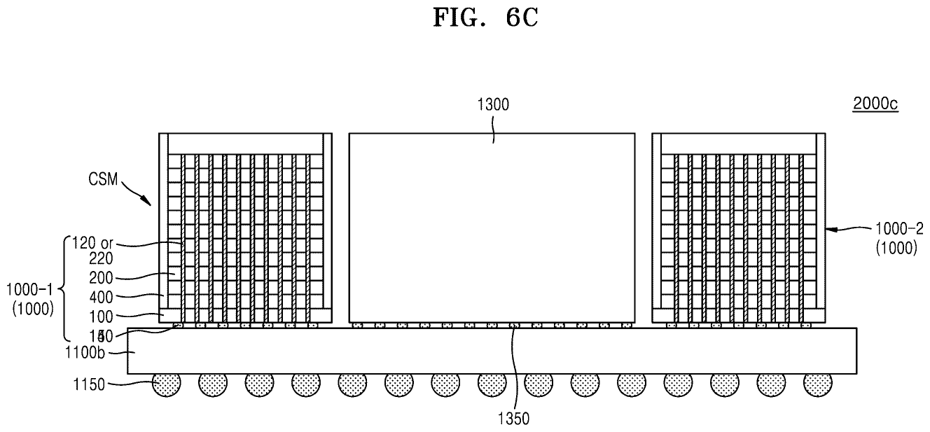

FIGS. 6A to 6C are cross-sectional views of system packages according to some embodiments and may each correspond to the cross-sectional view of the FIG. 5B. FIGS. 5A and 5B are also referred to for description, and repeated descriptions given with reference to FIGS. 1 to 5B are briefly made or omitted.

Referring to FIG. 6A, a system package 2000a of the present embodiment may be different from the system package 2000 of FIG. 5B in that the system package 2000a and may include a redistribution substrate 1200a and a Si-bridge 1400 instead of an interposer. Specifically, the system package 2000a of the present embodiment may include a semiconductor package 1000, a package substrate 1100, a redistribution substrate 1200a, a logic device 1300, a Si-bridge 1400, and an external sealant 1500. Descriptions of the semiconductor package 1000, the package substrate 1100, the logic device 1300, and the external sealant 1500 are the same as given in the descriptions of the system package 2000 of FIG. 5B. However, in the system package 2000a of the present embodiment, the semiconductor package 1000 and the logic device 1300 may be stacked on the redistribution substrate 1200a instead of the interposer 1200.

The redistribution substrate 1200a, like the interposer 1200, may be arranged between the package substrate 1100 and the semiconductor package 1000 and between the package substrate 1100 and the logic device 1300. The redistribution substrate 1200a is an RDL interposer and may correspond to an interposer for 2.3-dimensional (2.3D) package. For reference, interposers may be largely classified into 2.5D package interposers and 2.3D package interposers. A 2.5D package interposer may refer to a Si-interposer, such as the interposer 1200 of the system package 2000 of FIG. 5B, and may include a TSV therein. A 2.3D package interposer may refer to an organic or inorganic interposer including no TSV. An organic interposer may use polyimide (PI), benzocyclobutene (BCB), or polybenzooxazole (PBO) as a body layer, and an inorganic interposer may use ceramic or glass as a body layer. The 2.3D package interposer may be referred to as a panel-level package (PLP) interposer, a redistribution layer (RDL) interposer, or the like. The 2.3D package interposer may include, for example, a Si-bridge 1400 therein.

The function of the redistribution substrate 1200a may be similar to that of the interposer 1200 of the system package 2000 of FIG. 5B. However, although signal transfer between the semiconductor package 1000 and the logic device 1300 is performed via the interposer 1200 in the case of the system package 2000 of FIG. 5B, signal transfer between the semiconductor package 1000 and the logic device 1300 may be performed via the Si-bridge 1400 in the redistribution substrate 1200a in the case of the system package 2000a of the present embodiment.

In the system package 2000a of the present embodiment, the redistribution substrate 1200a may include a redistribution body layer 1201, a through-electrode 1210, a redistribution layer 1230, and a second connection terminal 1220. The redistribution body layer 1201 may include an organic or inorganic material, as described above. The redistribution layer 1230 may be arranged under the redistribution body layer 1201. In some embodiments, the redistribution layer 1230 may be arranged on the redistribution body layer 1201 or on and under the redistribution body layer 1201. The redistribution layer 1230 may include an interlayer dielectric, a redistribution line, a vertical via, and the like.

The through-electrode 1210 may have a structure extending through the redistribution body layer 1201. The through-electrode 1210 may connect external connection terminals 150 and 1350 of the semiconductor package 1000 and the logic device 1300 to the redistribution layer 1230. For example, the upper surface of the through-electrode 1210 may be connected to each of the external connection terminals 150 and 1350 of the semiconductor package 1000 and the logic device 1300, and the lower surface of the through-electrode 1210 may be connected to a redistribution line of the redistribution layer 1230.

The Si-bridge 1400 may be arranged in the redistribution substrate 1200a. For example, the Si-bridge 1400 may be arranged in the redistribution body layer 1201 of the redistribution substrate 1200a. The Si-bridge 1400 may connect the semiconductor package 1000 and the logic device 1300 to each other. Therefore, the Si-bridge 1400 may be arranged in the redistribution substrate 1200a in a region corresponding to a position between the semiconductor package 1000 and the logic device 1300. In addition, the Si-bridge 1400 may overlap both a portion of the semiconductor package 1000 and a portion of the logic device 1300.

The Si-bridge 1400 may be arranged in the redistribution body layer 1201 such that the Si-bridge 1400 is in contact with the redistribution layer 1230. However, in some embodiments, the Si-bridge 1400 may be arranged in the redistribution body layer 1201 such that the Si-bridge 1400 is not contact with the redistribution layer 1230. The Si-bridge 1400 may connect the semiconductor package 1000 and the logic device 1300 to each other by an inner wiring line thereof. In some embodiments, the Si-bridge 1400 may include a TSV therein and may connect the semiconductor package 1000 and the logic device 1300 to each other by the TSV and the redistribution layer 1230. In addition, in some embodiments, the Si-bridge 1400 may include a decoupling capacitor therein, and the decoupling capacitor may be connected to the logic device 1300.

Referring to FIG. 6B, a system package 2000b of the present embodiment may be different from the system package 2000a of FIG. 6A in that the system package 2000b includes no redistribution substrate 1200a. Specifically, the system package 2000b of the present embodiment may include a semiconductor package 1000, a package substrate 1100a, a logic device 1300, a Si-bridge 1400, and an external sealant 1500. Descriptions of the semiconductor package 1000, the logic device 1300, and the external sealant 1500 are the same as given in the descriptions of the system package 2000 of FIG. 5B. However, in the system package 2000b of the present embodiment, the semiconductor package 1000 and the logic device 1300 may be stacked directly on the package substrate 1100a instead of the interposer 1200.

The Si-bridge 1400 may be arranged in the package substrate 1100a. The Si-bridge 1400 may connect the semiconductor package 1000 and the logic device 1300 to each other. Therefore, the Si-bridge 1400 may be arranged in the package substrate 1100a in a region corresponding to a position between the semiconductor package 1000 and the logic device 1300. In addition, the Si-bridge 1400 may overlap both a portion of the semiconductor package 1000 and a portion of the logic device 1300. Other descriptions of the Si-bridge 1400 except for the above description are the same as given in the descriptions of the Si-bridge 1400 of the system package 2000a of FIG. 6A.

Referring to FIG. 6C, a system package 2000c of the present embodiment may be different from the system package 2000b of FIG. 6B in that the system package 2000c includes no Si-bridge 1400. Specifically, the system package 2000c of the present embodiment may include a semiconductor package 1000, a package substrate 1100b, a logic device 1300, and an external sealant 1500. Descriptions of the semiconductor package 1000, the logic device 1300, and the external sealant 1500 are the same as given in the descriptions of the system package 2000 of FIG. 5B. However, in the system package 2000c of the present embodiment, the semiconductor package 1000 and the logic device 1300 may be stacked directly on the package substrate 1100b instead of the interposer 1200.

In the system package 2000c of the present embodiment, pads arranged on the upper surface of the package substrate 1100b may have a fine pitch. In other words, the pads arranged on the upper surface of the package substrate 1100b may have a pitch corresponding to the external connection terminals 150 and 1350 of the semiconductor package 1000 and the logic device 1300. Therefore, the external connection terminals 150 and 1350 of the semiconductor package 1000 and the logic device 1300 may be respectively coupled and connected directly to the pads on the upper surface of the package substrate 1100b. Uppermost wiring lines of the package substrate 1100b, which are connected to the pads, may have a fine pitch in correspondence with the fine pitch of the pads of the package substrate 1100b. For example, the pads and the uppermost wiring lines of the package substrate 1100b may have widths and intervals of about 2 μm. Wiring lines under the uppermost wiring lines may have widths and intervals of about 10 μm that is greater than 2 μm. However, the widths and intervals of the pads and the uppermost wiring lines and the widths and intervals of the wiring lines under the uppermost wiring lines are not limited to the numerical range set forth above.

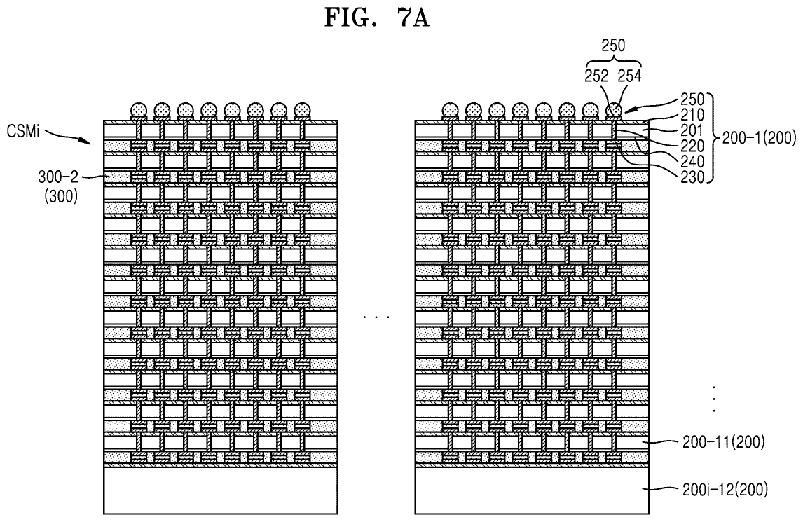

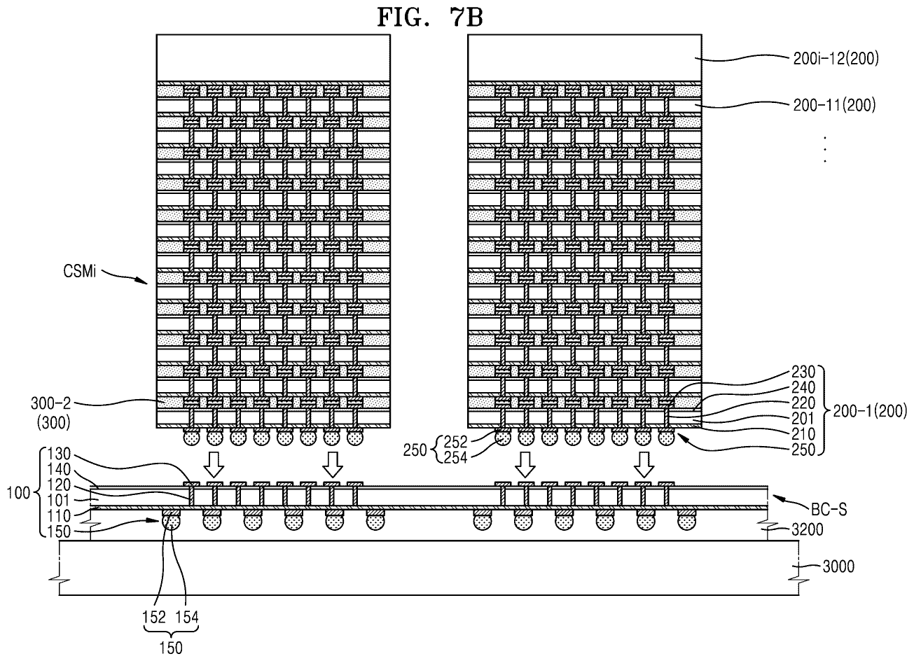

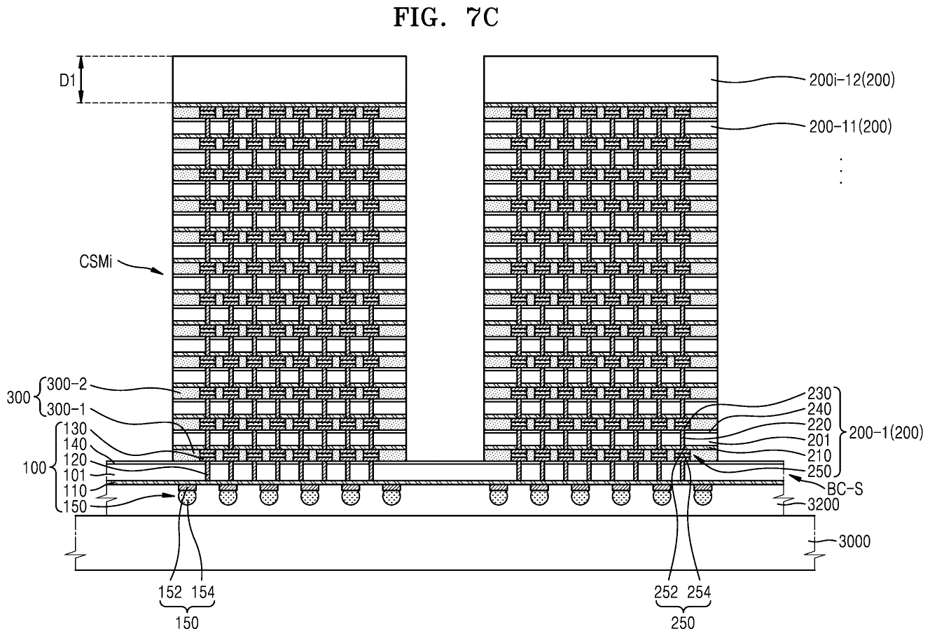

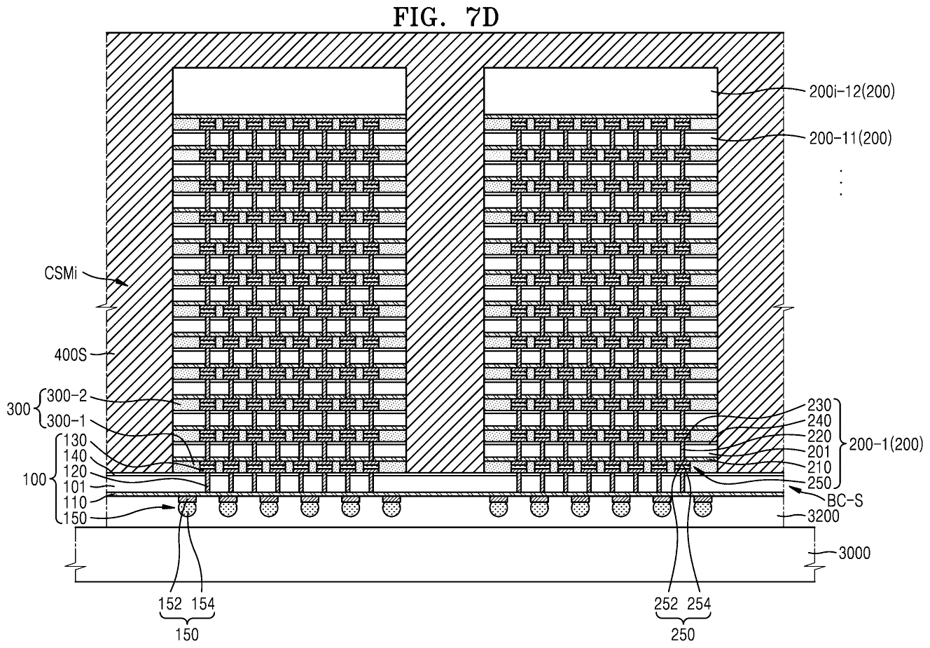

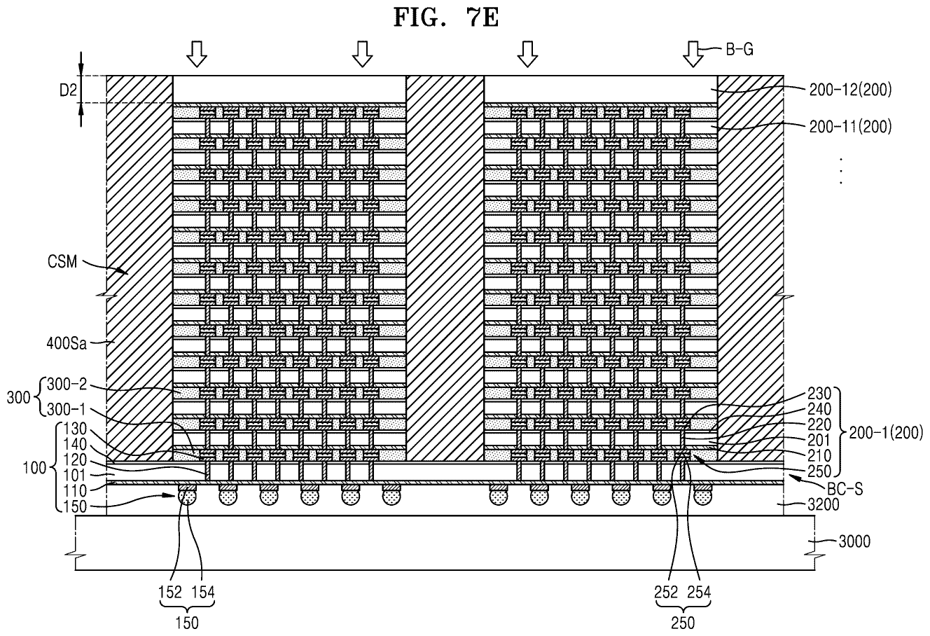

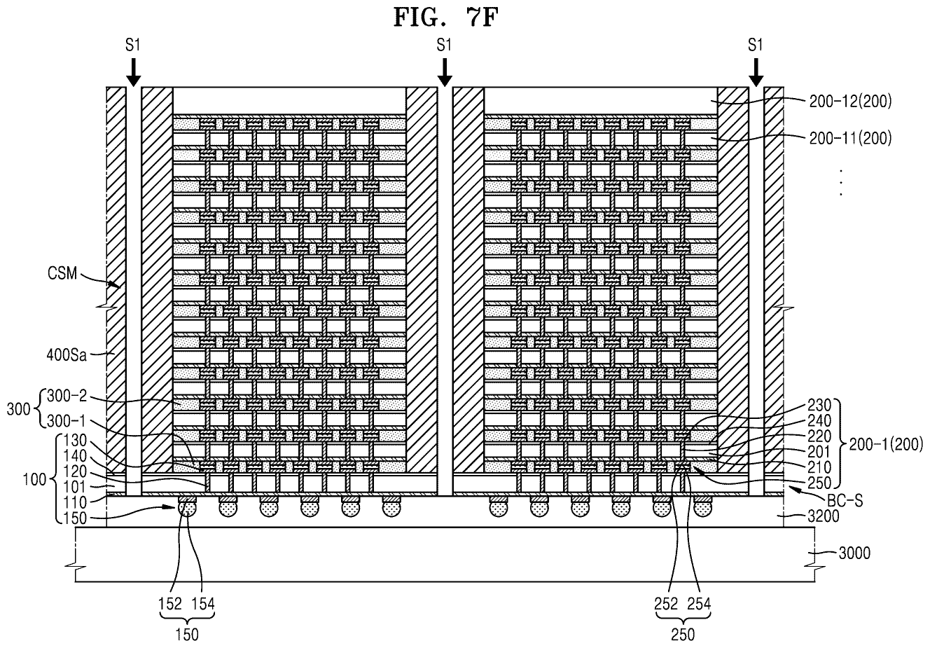

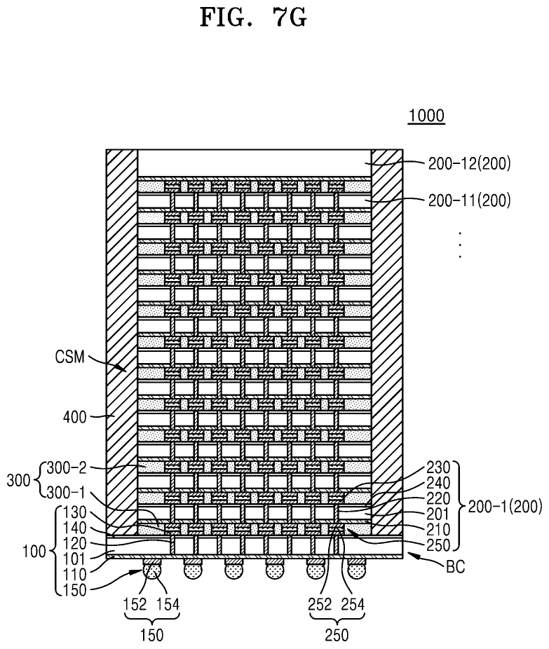

FIGS. 7A to 7G are cross-sectional views schematically illustrating processes of a method of fabricating a semiconductor package, according to an embodiment. FIG. 1 is also referred to for description, and repeated descriptions given with reference to FIGS. 1 to 6C are briefly made or omitted.

Referring to FIG. 7A, in the method of fabricating a semiconductor package, according to the present embodiment, a plurality of initial chip stack modules CSMi are fabricated first. Each of the initial chip stack modules CSMi may include a plurality of memory chips 200. Descriptions of the initial chip stack module CSMi are the same as the descriptions of the chip stack module CSM of the semiconductor package 1000 of FIG. 1. However, the thickness of the top memory chip, that is, a twelfth memory chip 200i-12, in the initial chip stack module CSMi may be greater than the thickness of the twelfth memory chip 200-12 of the chip stack module CSM of the semiconductor package 1000 of FIG. 1. In FIG. 7A, the initial chip stack modules CSMi are each illustrated upside down as compared with the chip stack module CSM of the semiconductor package 1000 of FIG. 1. A specific method of fabricating the plurality of initial chip stack modules CSMi is described below with reference to FIGS. 8A and 8B.

Referring to FIGS. 7B and 7C, after the initial chip stack modules CSMi are fabricated, each of the initial chip stack modules CSMi is stacked on a base chip 100, which corresponds thereto, of a base chip substrate BC-S. Here, the base chip substrate BC-S may have a wafer shape and may include a plurality of base chips 100. In the stacking process of the initial chip stack modules CSMi, the base chip substrate BC-S may be bonded and secured onto a carrier substrate 3000 via a substrate bonding layer 3200.

In the stacking process of the initial chip stack modules CSMi, the lowermost memory chip 200, that is, the first memory chip 200-1, in each of the initial chip stack modules CSMi may face the base chip substrate BC-S. In addition, each of the initial chip stack modules CSMi may be stacked on the corresponding base chip 100 of the base chip substrate BC-S via the bump 250 and the bonding layer 300 on the lower surface of the first memory chip 200-1. Here, the bonding layer 300 may correspond to a module-chip bonding layer 300-1. The stacking process of the initial chip stack modules CSMi may be performed by a TCB method. As shown in FIG. 7C, the top memory chip, that is, the twelfth memory chip 200i-1, in each of the initial chip stack modules CSMi may have a first thickness D1.

Referring to FIG. 7D, after the initial chip stack modules CSMi are stacked, a sealant 400S is formed to seal the initial chip stack modules CSMi on the base chip substrate BC-S. As shown in FIG. 7D, the sealant 400S may cover all the initial chip stack modules CSMi on the base chip substrate BC-S. Specifically, the sealant 400S may cover the side surface and the upper surface of each of the initial chip stack modules CSMi. In addition, the sealant 400S may fill a space between adjacent initial chip stack modules CSMi.

Referring to FIG. 7E, next, respective upper portions of the initial chip stack modules CSMi and an upper portion of the sealant 400S are removed by a back-grinding process B-G. After the back-grinding process B-G, the initial chip stack module CSMi may become a chip stack module CSM. Therefore, the thickness of the top memory chip, that is, the twelfth memory chip 200-12, of the chip stack module CSM may be substantially equal to the thickness of the twelfth memory chip 200-12 of the hip stack module CSM of the semiconductor package 1000 of FIG. 1. For example, the twelfth memory chip 200-12 of the chip stack module CSM may have a second thickness D2, and the second thickness D2 may be less than the first thickness D1.

A sealant 400Sa after the back-grinding process B-G may be thinner than the sealant 400S before the back-grinding process B-G. In addition, after the back-grinding process B-G, the upper surface of the sealant 400Sa may be substantially coplanar with the upper surface of the chip stack module CSM, that is, the upper surface of the twelfth memory chip 200-12.

For reference, the thickness of the twelfth memory chip 200-12 of the chip stack module CSM may be adjusted according to a thickness specification of a semiconductor package. In other words, after the chip stack module CSM including the twelfth memory chip 200-12 having a relatively high thickness is fabricated, the thickness of the twelfth memory chip 200-12 may be adjusted by the back-grinding process B-G, thereby adjusting the total thickness of the semiconductor package to comply with the thickness specification.

Referring to FIGS. 7F and 7G, after the back-grinding process B-G, the base chip substrate BC-S and chip stack modules CSM on the base chip substrate BC-S are individualized by a first sawing process S1. After the first sawing process S1, base chips 100 and the chip stack modules CSM on the base chips 100 may be separated from the carrier substrate 3000, thereby fabricating a semiconductor package 1000 as in FIG. 7G. The semiconductor package 1000 of FIG. 7G may be substantially identical to the semiconductor package 1000 of FIG. 1.

When the semiconductor package 1000c of FIG. 4A is fabricated, in the first sawing process S1, individualization may be performed such that two chip stack modules CSM are arranged on a base chip BCa. The base chip BCa may include two base chip portions respectively corresponding to the two chip stack modules CSM.

FIGS. 8A and 8B are cross-sectional views schematically illustrating a process of fabricating the initial chip stack module of FIG. 7A. FIG. 1 is also referred to for description, and repeated descriptions given with reference to FIGS. 1 to 7G are briefly made or omitted.

Referring to FIG. 8A, in the fabrication process of the initial chip stack module CSMi, first memory chips 200 are stacked on a top memory substrate 200TS. Here, the top memory substrate 200TS may have a wafer shape and may include a large number of top memory chips. Each of the top memory chips of the top memory substrate 200TS may correspond to the top memory chip, for example, the twelfth memory chip 200i-12, in the initial chip stack module CSMi. The top memory substrate 200TS may have a relatively high thickness, for example, a first thickness D1, and may function as a support substrate in a stacking process of the memory chips 200.

In the stacking process of the memory chips 200, a plurality of memory chips 200 may be stacked on a top memory chip, which corresponds thereto, of the top memory substrate 200TS. The number of memory chips 200 stacked on one top memory chip may be one less than the number of memory chips that are included in the initial chip stack module CSMi. For example, when the initial chip stack module CSMi includes twelve memory chips 200, eleven memory chips 200 may be stacked on the corresponding top memory chip of the top memory substrate 200TS. Each of the memory chips 200 may be stacked on the corresponding top memory chip of the top memory substrate 200TS via a bump 250 and a bonding layer 300a. Here, the bonding layer 300a may correspond to an inter-chip bonding layer 300a-2. The stacking process of the memory chips 200 may be performed by a TCB method. Therefore, the bonding layer 300a may include a protrusion F1, as shown in FIG. 8A.

Referring to FIG. 8B, a required number of memory chips 200 are stacked on each of the top memory chips of the top memory substrate 200TS, and then, the top memory substrate 200TS and the memory chips 200 on the top memory substrate 200TS are individualized by a second sawing process S2. After the second sawing process S2, the top memory chip of the top memory substrate 200TS, and the memory chips 200 on the top memory chip may constitute the initial chip stack module CSMi.

The second sawing process S2 may be performed by using a relatively thick blade BL. Therefore, in the second sawing process S2, respective outer portions of the bonding layer 300a and the memory chips 200 may be removed as shown in FIG. 8B. In FIG. 8B, the quadrangle in the center indicates the blade BL, and dashed-line quadrangles on both the left and right sides indicate regions that are to be removed by the second sawing process S2. As such, the respective outer portions of the bonding layer 300a and the memory chips 200 are removed together in the second sawing process S2, and thus, after the second sawing process S2, the side surface of the bonding layer 300 may be substantially coplanar with the side surface of the memory chip 200.

FIG. 9 is a cross-sectional view schematically illustrating a process of fabricating the initial chip stack module of FIG. 7A. FIGS. 2A and 8A are also referred to for description, and repeated descriptions given with reference to FIGS. 1 to 8B are briefly made or omitted.

Referring to FIG. 9, in the fabrication process of the initial chip stack module CSMi, first, memory chips 200 are stacked on each of the top memory chips of the top memory substrate 200TS, as shown in FIG. 8A. A required number of memory chips 200 are stacked on each of the top memory chips of the top memory substrate 200TS, and then, the top memory substrate 200TS and the memory chips 200 on the top memory substrate 200TS are individualized by a second sawing process S2′. After the second sawing process S2′, the top memory chip of the top memory substrate 200TS, and the memory chips 200 on the top memory chip may constitute an initial chip stack module CSMai.

The second sawing process S2′ may be performed by using a relatively thin blade BL'. Therefore, in the second sawing process S2′, respective outer portions of the bonding layer 300a and the memory chips 200 may be maintained without being removed, as shown in FIG. 9. As such, the respective outer portions of the bonding layer 300a and the memory chips 200 are maintained in the second sawing process S2′, and thus, the bonding layer 300a may include a protrusion F1 protruding from the side surface of the memory chip 200.

The processes of FIGS. 7A to 7F may be performed by using the initial chip stack module CSMai, thereby fabricating the semiconductor package 1000a of FIG. 2A. The initial chip stack module CSMai may become a chip stack module CSMa by thinning the top memory chip, for example, the twelfth memory chip 200-1, in the back-grinding process B-G of FIG. 7E. In addition, in the first sawing process S1 of FIG. 7F, the individualization may be performed such that two chip stack modules CSMa are arranged on the base chip BCa, thereby fabricating the semiconductor package 1000f of FIG. 4B.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts have been particularly shown and described with reference to embodiments thereof, it will be understood that various changes in form and details may be made therein without departing from the spirit and scope of the following claims.

1. A semiconductor package comprising:
a base chip;
at least one chip stack module on the base chip; and
a sealant on the base chip and sealing the at least one chip stack module, wherein each chip stack module of the at least one chip stack module has an integral structure, in which a plurality of memory chips are stacked and uniform, and
each chip stack module of the at least one chip stack module is on the base chip while having the integral structure.

2. The semiconductor package of claim 1, further comprising:
a bonding layer between the base chip and the at least one chip stack module and between an adjacent two memory chips of the plurality of memory chips,
wherein a side surface of the bonding layer is coplanar with a side surface of the at least one chip stack module or the side surface of the bonding layer is coplanar with side surfaces of each of the plurality of memory chips.

3. The semiconductor package of claim 1, further comprising:
a bonding layer between the base chip and the at least one chip stack module and between an adjacent two memory chips of the plurality of memory chips,
wherein a portion of the bonding layer protrudes from a side surface of each of the plurality of memory chips.

4. The semiconductor package of claim 1, wherein
the at least one chip stack module includes a plurality of chip stack modules on the base chip, and
the sealant fills a space between adjacent chip stack modules among the plurality of chip stack modules.

5. The semiconductor package of claim 4, wherein
the sealant covers an outer side surface of each of the plurality of chip stack modules,
a side surface of the sealant is coplanar with a side surface of the base chip, and
an upper surface of the sealant is coplanar with an upper surface of each of the plurality of chip stack modules.

6. The semiconductor package of claim 1, wherein
the base chip is a logic chip, the base chip includes a controller, and
the controller is configured to control signal transfer between the at least one chip stack module and an external device.

7. The semiconductor package of claim 1, wherein, in each chip stack module of the at least one chip stack module,
the plurality of memory chips include 4n memory chips,
the 4n memory chips include an uppermost memory chip on other memory chips,
the other memory chips each comprise a through-electrode and the uppermost memory chip does not include the through-electrode, and
n of the 4n memory chips is a natural number.

8. The semiconductor package of claim 1, further comprising:
a bump and a bonding layer, wherein
an adjacent two memory chips among the plurality of memory chips are coupled to each other via the bump and the bonding layer.

9. The semiconductor package of claim 1, further comprising:
an interposer or a package substrate; and
an external connection terminal on a lower surface of the base chip,
wherein the semiconductor package is stacked via the external connection terminal on the interposer or the package substrate.

10. The semiconductor package of claim 1, wherein
each of the plurality of memory chips is a dynamic random-access memory (DRAM) chip, and
the semiconductor package is a high-bandwidth memory (HBM) package.

11. A semiconductor package comprising:
a chip stack module having an integral structure, in which 4n memory chips are stacked and uniform, the chip stack module including a bonding layer being between an adjacent two memory chips among the 4n memory chips, and n being a natural number, wherein
the 4n memory chips include an uppermost memory chip on other memory chips,
the other memory chips each include a through-electrode,
the uppermost memory chip does not include the through-electrode, and
a portion of the bonding layer protrudes from a side surface of each memory chip among the 4n memory chips, or
a side surface of the bonding layer is coplanar with a side surface of each of the 4n memory chips.

12. The semiconductor package of claim 11, further comprising:
a base chip under the chip stack module; and
a sealant on the base chip and sealing the chip stack module.

13. The semiconductor package of claim 12, wherein
the chip stack module is one chip stack module among a plurality of chip stack modules on the base chip,
the sealant fills a space between adjacent chip stack modules among the plurality of chip stack modules,
the sealant covers an outer side surface of each of the plurality of chip stack modules, and
a side surface of the sealant is coplanar with a side surface of the base chip.

14. The semiconductor package of claim 11, further comprising:
an interposer or a package substrate; and
an external connection terminal, wherein
each of the 4n memory chips is a dynamic random-access memory (DRAM) chip,
the semiconductor package is a high-bandwidth memory (HBM) package,
the semiconductor package is stacked via the external connection terminal on the interposer or the package substrate via, and
the external connection terminal is on a lower surface of the chip stack module or the external connection terminal is on a lower surface of a base chip under the chip stack module.

15. A semiconductor package comprising:
a package substrate;
at least one upper package on the package substrate; and
a logic device on the package substrate and adjacent to the at least one upper package, wherein
the at least one upper package includes a chip stack module having an integral structure in which a plurality of memory chips are stacked and uniform.

16. The semiconductor package of claim 15, wherein the at least one upper package further comprises:
a base chip under the chip stack module; and
a sealant on the base chip and sealing the chip stack module.

17. The semiconductor package of claim 16, further comprising:
a bonding layer between the base chip and the chip stack module, wherein
the bonding layer is between an adjacent two memory chips among the plurality of memory chips, and
a side surface of the bonding layer is coplanar with a side surface of the chip stack module, or
the side surface of the bonding layer is coplanar with each memory chip among the plurality of memory chips, or
a portion of the bonding layer protrudes from the side surface of each memory chip among the plurality of memory chips.

18. The semiconductor package of claim 16, wherein
the base chip is a logic chip, and
the base chip comprises a controller configured to control signal transfer between the chip stack module and the logic device.

19. The semiconductor package of claim 15, further comprising:
a bump and a bonding layer, wherein,
in the at least one upper package, an adjacent two memory chips among the plurality of memory chips are coupled to each other via the bump and the bonding layer.

20. The semiconductor package of claim 15, further comprising:
a medium substrate on the package substrate,
wherein the at least one upper package and the logic device are stacked on the medium substrate.

21-26. (canceled)
